(19) United States
(12) Patent Application Publication
(10) Pub. No.: US 2007/0230109 A1
(43) Pub. Date: Oct. 4, 2007

(54) HIGH DENSITY ARRAY SYSTEM WITH ACTIVE STORAGE BLADES

(75) Inventors: Matthew Thomas Starr, Lafyette, CO (US); Walter Wong, Boulder, CO (US); Micheal Edward Figero, Golden, CO (US); Ronald Gregory Duren, Denver, CO (US); Matthew John Ninesling, Littleton, CO (US); Joshua Daniel Carter, Lafyette, CO (US); Scott Edward Bacom, Westminster, CO (US)

Correspondence Address: SPECTRA LOGIC;c/o HISCOCK & BARCLAY, LLP, 100 CHESTNUT STREET, 2000 HSBC PLAZA, ROCHESTER, NY, 14604-2404, US

(73) Assignee: Spectra Logic Corporation

(21) Appl. No.: 11/626,203

(22) Filed: Jan. 23, 2007

Related U.S. Application Data
(60) Provisional application No. 60/788,487, filed on Mar. 31, 2006.

(51) Int. Cl. G06F 1/16; H05K 5/00

(52) U.S. Cl. 361/685; 361/724

(57) ABSTRACT

A storage system having at least one storage unit, the storage unit including a frame that defines a storage unit interior space, at least one media blade capable of removably supporting a plurality of storage elements wherein the media blade is adapted to provide a communicating path between the storage elements and the storage unit. The media blade is capable of moving between a retracted position wherein substantially all of the storage elements are within the interior space and an extended position wherein substantially all of the storage elements are external to the interior space. Power and communication are provided to the media blade when the media blade is at or between the retracted and extended positions the power and communication is uninterrupted.

### CROSS-REFERENCE TO RELATED APPLICATIONS

This application is a non-provisional application of provisional U.S. Ser. No. 60/788,487, entitled HIGH DENSITY ARRAY SYSTEM WITH ACTIVE STORAGE BLADES, filed Mar. 31, 2006 which is incorporated herein by reference.

### FIELD OF THE INVENTION

The present invention is directed to a storage unit that is useful in storing data to any one of a plurality of storage elements associated with a frame that can be moved at least partially out of the storage unit without power and communication interruption to the storage elements.

### BACKGROUND OF THE INVENTION

Presently, data storage units, such as mass data storage libraries and RAID (Redundant Array of Independent Disks/Drives) systems, each employing multiple storage elements, are primarily used to archive data, i.e., store data that is not immediately needed by the host computer, and provide archived data to the host computer when the data is needed. To elaborate, a typical data storage unit receives data from a host computer and causes the data to be stored or recorded on a recording medium typically located in one or more of the storage elements, such as a disk drive for example. When the host computer requires some of the data that was previously stored in the storage elements, a request for the data is sent from the host computer to the data storage unit to fulfill real-time data retrieval needs. In response, the data storage unit retrieves the data from the storage elements) and transmits the retrieved data to the host computer system.

From time to time, there may be reason to remove one or more storage elements from a data storage unit, such as for repair, maintenance or upgrades. This generally results in removing panels associated with a data storage unit cover in order to access the storage elements inside the data storage unit. Typically, the process of removing one or more storage elements from a data storage unit further requires turning off the power to the data storage unit.

In an effort to improve accessing powered storage elements operable with a data storage unit both methods and apparatus are disclosed herein. It is to innovations related to this subject matter that the claimed invention is generally directed.

### SUMMARY OF THE INVENTION

The present invention relates generally to a storage unit that is useful in storing data to any one of a plurality of storage elements supported by a drawer-like structure that can be moved at least partially out of the storage unit without power and communication interruption to the storage elements.

Embodiment of the present invention can therefore comprise a storage unit comprising: a frame defining a storage unit interior space; at least one media blade adapted for accommodating a plurality of storage elements; the media blade adapted to provide at least a communication pathway and power between the storage elements and the storage unit; the media blade adapted for being at least partially moved into and out from the interior space without interruption of the power and communication.

Another embodiment of the present invention can therefore comprise a storage unit comprising a frame that defines and interior space, the storage unit capable of performing the steps of: receiving a first data package from a host; storing the first data package on a first media blade wherein the first media blade comprises a plurality of data storage elements; moving the first media blade along a guided pathway adapted for the first media blade from a first position that is substantially within the interior space to a second position that is less than substantially within the interior space without interrupting the storing.

Yet another embodiment of the present invention can therefore comprise a storage system comprising at least one storage unit, the storage unit comprising: a frame defining a storage unit interior space; at least one media blade capable of removably supporting a plurality of storage elements wherein the media blade is adapted to provide a communicating path between the storage elements and the storage unit; the media blade capable of moving between a retracted position wherein substantially all of the storage elements are within the interior space and an extended position wherein substantially all of the storage elements are external to the interior space; a means to provide uninterrupted power and communication to the media blade when the media blade is at or between the retracted and extended positions.

### BRIEF DESCRIPTION OF THE DRAWINGS

FIG. 1A is a block diagram of a data storage arrangement constructed in accordance with an embodiment of the present invention.

FIG. 1B shows a commercial embodiment of a High Density Array (HDA) unit consistent with embodiments of the present invention.

FIG. 1C is a side view of the HDA unit illustrating one embodiment of a means to provide uninterrupted power and communication to a storage media blade when the storage media blade is moved between a retracted and extended position.

FIG. 1D is a side view of the HDA unit illustrating an alternative embodiment of a means to provide uninterrupted power and communication to a storage media blade when the storage media blade is moved between a retracted and extended position.

FIG. 1E is a side view of the HDA unit illustrating yet another alternative embodiment of a means to provide uninterrupted power and communication to a storage media blade when the storage media blade is moved between a retracted and extended position.

FIG. 2A is one commercial configuration of a storage media blade populated with ten disc drives consistent with embodiments of the present invention.

FIG. 2B shows a back view of the storage media blade populated with nine disc drives consistent with embodiments of the present invention.

FIG. 2C shows the back side of a bezel module consistent with embodiments of the present invention.

FIG. 3 shows the storage media blade of FIG. 2A without disc drives consistent with embodiments of the present invention.

FIG. 4 shows an embodiment consistent with the present invention of a retaining mechanism of the illustrative commercial HDA embodiment in more detail.

FIG. 5 shows an embodiment consistent with the present invention of a top view of a blade plate board of the illustrative commercial HDA embodiment in more detail.

FIG. 6 shows an embodiment consistent with the present invention of an illustration of a blade board schematic layout of the blade plate board of FIG. 5.

FIG. 7 is an illustrative embodiment of one optional configuration of an HDA unit schematic layout consistent with embodiments of the present invention.

FIG. 8A is an illustration of an interconnected multi-HDA system schematic layout consistent with embodiments of the present invention.

FIG. 8B is an illustration of a master HDA and add-on storage media unit layout consistent with embodiments of the present invention.

FIG. 8C is an illustration of a looped connected multi-HDA system schematic layout consistent with embodiments of the present invention.

FIG. 9 shows the commercial embodiment of an HDA unit with the back surface presented consistent with embodiments of the present invention.

FIG. 10 shows the commercial embodiment of an HDA unit with the back surface presented without the removable panel and a server module partially removed consistent with embodiments of the present invention.

FIG. 11 is a block diagram of a top view of the HDA unit without the cover and removable panel consistent with embodiments of the present invention.

### DETAILED DESCRIPTION

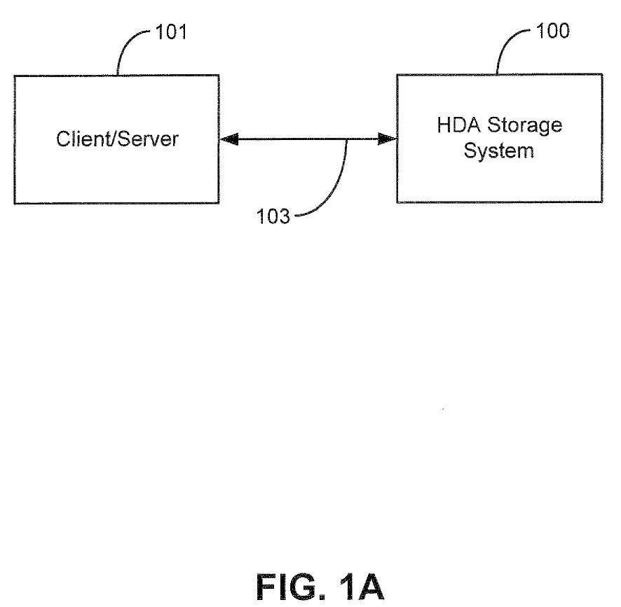

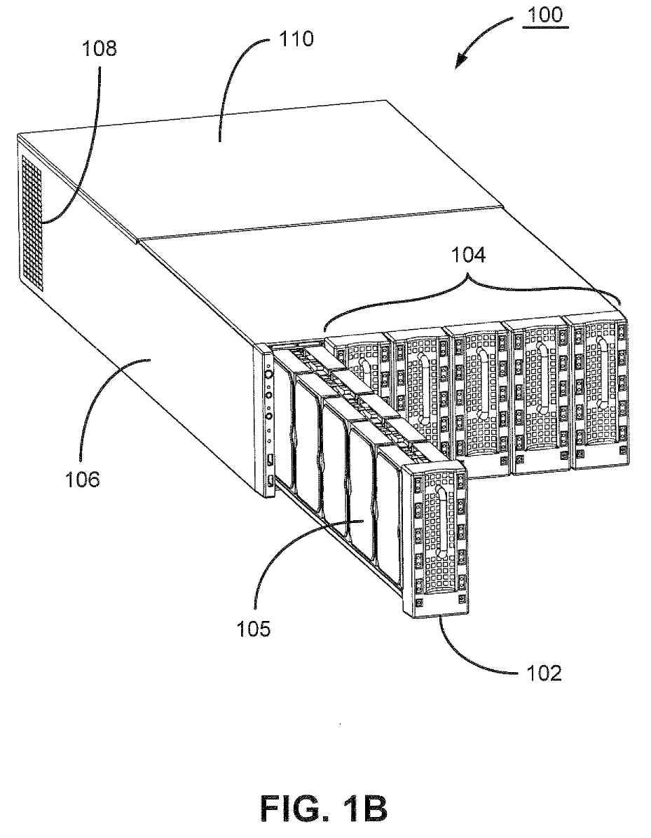

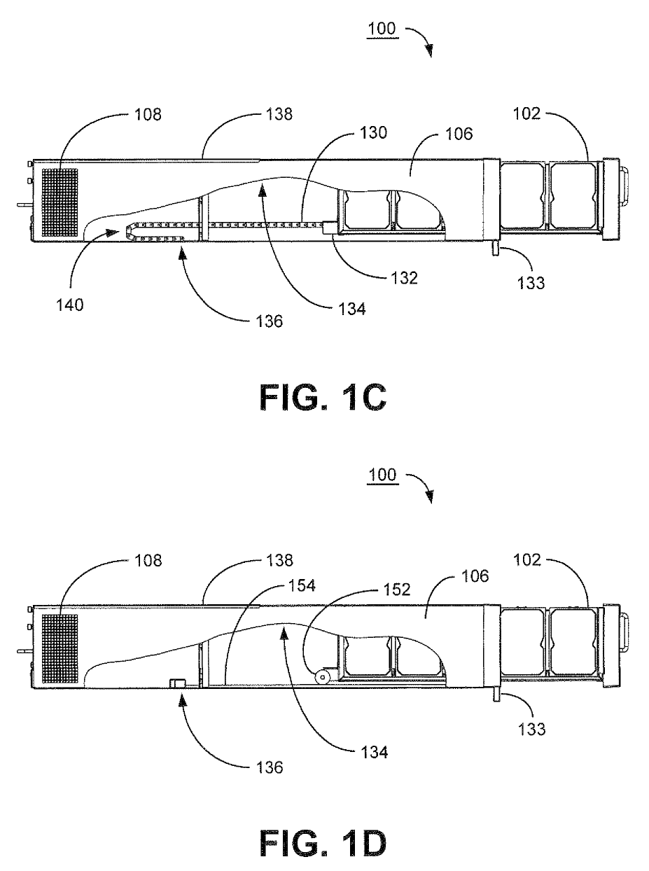

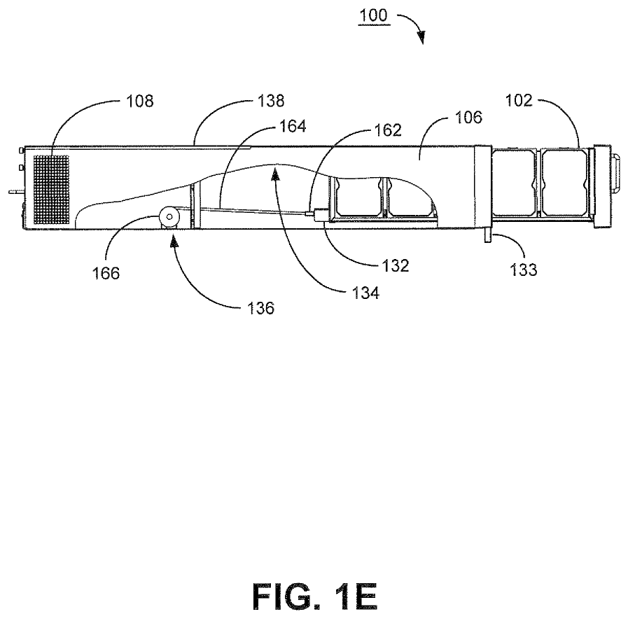

Referring to the drawings in general, and more specifically to FIG. 1A, shown therein is a block diagram of a data storage arrangement constructed in accordance with an embodiment of the present invention. In what follows, similar or identical structure is identified using identical callouts.

The data storage arrangement illustrated in FIG. 1A can comprise a client/server 101 in communication 103 with a High Density Array (HDA) data storage system 100. The client/server 101 can be a host computer or some other consumer/producer of data; other embodiments can also include another storage library or a streaming output device, such as a video server, to name several examples. The client 101 is an entity, or entities, that is capable of ‘taking in’ data, for example a client/serve 101 is a consumer when receiving data and an HDA 100 is a consumer when receiving data. As one skilled in the art will appreciate, in addition to ‘taking in’ data, a consumer of data is also generally capable of manipulating and/or transmitting data. The client 101 can be a personal computer, a main frame computer, a server, or any computer system operatively linked to the HDA 100, to name a few examples. The communication path 103, at a minimum, needs only to facilitate communication between the client/server 101 and the HDA 100. The means for communication can be accomplished by a dedicated pathway (such as a SCSI [Small Computer Systems Interface] cabled connection), fiber-channel or, in an alternative embodiment, a pathway over a network (such as a LAN, WAN, or other communication architecture), for example. Furthermore, the communication path can be in the form of (not to be limited by) a wire line pathway, wireless, fiber channel or a combination thereof.

Embodiments of the present invention can be commercially practiced in a Spectra Logic HDA manufactured by Spectra Logic of Boulder Colorado. FIG. 1B shows a commercial embodiment of one HDA unit 100 with a first storage media blade 102, comprising ten disc drives 105, in an extended position and five additional storage media blades 104, each capable of comprising ten disc drives 105, or less, in a fully retracted position. A media blade 104 can be optimized for load balancing, power balancing, capacity balancing, etc. Power and communication can be provided to the storage media blades 102 and 104 without interruption regardless of whether the storage media blades 102 and 104 are in a retracted position, extended position, or a position there between. In other words, the storage media blade 104 can be in a power state independent of the location of the blade 104. Each blade 102 and 104 can be configured to store data with back-up capabilities such as in a RAID (Redundant Array of Inexpensive Disc [drives]) configuration, for example RAID level-5 or RAID level-6, or without redundancy. In an alternative embodiment, back-up configurations can be accomplished by writing redundant data across different blades 102 and 104 or across multiple HDA units that are interconnected. As one skilled in the art will appreciate, there are numerous RAID configurations which are optimized to an end user's desire to balance storage speed performance with redundancy of data. The HDA unit 100 is substantially encased on four sides (top, bottom, left side and right side) by a cover 106 and a removable panel 110 which define an interior space of the HDA unit 100. A vent 108 is provided in the cover 106 for cooling purposes which, as known by a skilled artisan, is not limited by quantity, size or location.

FIG. 1C is a side view of the HDA unit 100 illustrating one embodiment of a means to provide uninterrupted power and communication to a storage media blade 102 when the storage media blade 102 is moved between a retracted and extended position. As revealed through the cutaway 134 in the cover 106, power and communication are provided to the storage media blade 102 from the HDA unit 100 via a flex cable (not shown) supported by a flex chain linkage 130 (or other equivalent flexible cable carier), such as an IGUS chain from IGUS Corporation of Koln, Germany, that connects to the HDA unit 100 at a back plane connector 136 and the storage media blade 102 at a blade connector 132. Alternatives to a flex cable can include a flexible ribbon cable or flexible individual or semi-individual group of wires (such as one or more ipass cables provided by Molex Corporation of San Jose, Calif.) just to name several examples that can accomplish the same functionality without deviating from the present invention. The flex cable linkage 130 tracks the movement of the storage media blade 102 providing uninterrupted power and communication from a retracted position to an extended position without binding or tangling, as shown by the pivoting links to form a bend 140 in the linkage 130. In one embodiment, a blade latch mechanism 133, such as a Richco R1001 card inserter/extractor, of Richco Inc., of Morton Groove, Ill., can be provided to limit the extension of the storage media blade 102 thus retaining a portion of the blade 102 in the HDA unit 100 for stability and support when in the extended position (for an operator to access the disc drives 105, or an alternative data storage device, associated with the blade 102). The blade latch mechanism 133 can be manipulated to unlatch the storage media blade 102 allowing removal of the blade 102 from the HDA unit 100.

FIG. 1D is a side view of the HDA unit 100 illustrating an alternative embodiment of a means to provide uninterrupted power and communication to a storage media blade 102 when the storage media blade 102 is moved between a retracted and extended position. As revealed through the cutaway 134 in the cover 106, power and communication are provided to the storage media blade 102 via a conductive wheel 152 (or optionally a brush system) that is in contact with a conductive path 154 connected to a back plane connector 136, for example. As the storage media blade 102 is moved between a retracted position and a fully extended position, the conductive wheel 152 can continuously provide power and communication to the blade 102 while in contact with the conductive path 154. Optionally, the conductive wheel 152 and conductive path 154 can provide only power with data transmitted wirelessly. The blade latch mechanism 133, as previously described, can serve the purpose of retaining the storage media blade 102 partially in the HDA unit 100 unless made to disengage the blade 102 from the unit 100.

FIG. 1E is a side view of the HDA unit 100 illustrating yet another embodiment of a means to provide uninterrupted power and communication to a storage media blade 102 when the storage media blade 102 is moved between a retracted and extended position. As revealed through the cutaway 134 in the cover 106, power and communication are provided to the storage media blade 102 via a flex cable 164 that connects to the HDA unit 100 at a back plane connector 136 and the storage media blade 102 at a blade connector 132. In this embodiment, the flex cable 164 maintains tension via a spring-loaded spindle 166, in order to prevent binding or tangling. As one skilled in the art will appreciate, FIGS. 1B, 1C and 1D are illustrative of the many optional ways to provide uninterrupted power and communication to a storage media blade 102 when moved between a retracted and extended position.

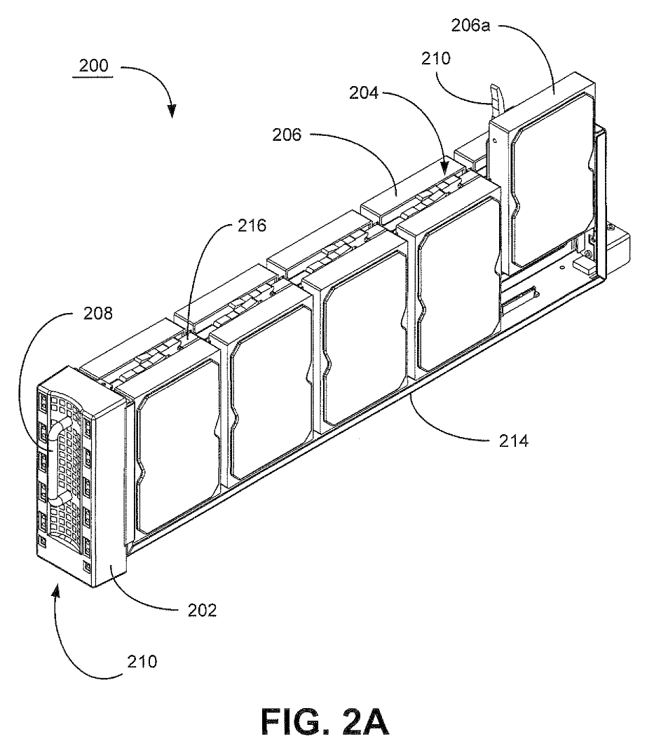

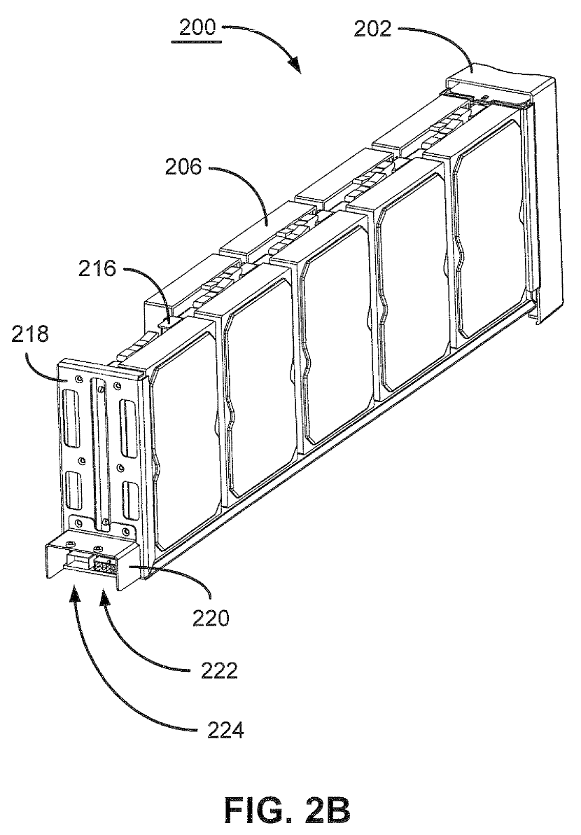

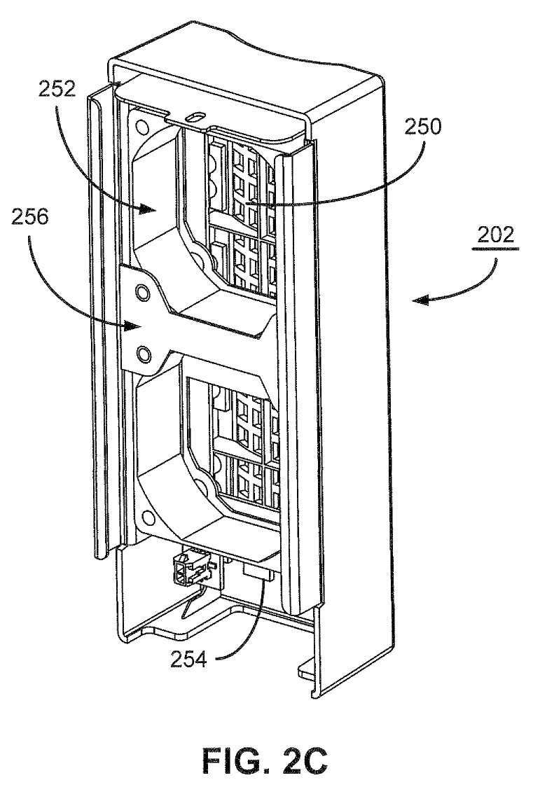

With reference to FIG. 2A, shown therein is one commercial configuration of a storage media blade 200 populated with ten 3.5 inch form factor disc drives 206, such as a Barracuda class disc drive manufactured by Seagate Corporation of Scotts Valley, Calif. In an alternative embodiment, the storage media blade 200 can accommodate different form factor drives, such as 2.5 inch disc drive and 3.5 inch disc drive for example. Optionally, the storage blade 200 may be limited to accommodating a specific form factor disc drive or alternate kind of medium, such as flash memory cards, or a combination therein, for example. In yet another alternative embodiment, the storage blade 200 may comprise disc drives with different storage capacities (wherein, in one embodiment, the lowest capacity drive may be the determining capacity of all other drives on the blade 200) and storage speeds. In addition to the disc drives 206, one embodiment of the storage media blade 200 can comprises a bezel module 202 with a handle 208 at a front end 210, a blade plate 214 which supports a blade plate board (not shown) for providing power to the disc drives 206 and a mid-plane frame 216 shown interposed between the drives 206 which can cooperate with retaining mechanisms 204 wherein a retaining mechanism 204 can further comprise a latch 210. As illustrated, a disc drive 206a is partially ejected from the blade plate 214. In this embodiment, the disc drives 206 are oppositely disposed relative the mid-plane frame 216 providing the added advantage of oppositely rotating discs (not shown) comprised by the disc drives 206 reducing the vibration of the storage media blade 200 when fully populated. Additional vibration control means can be provided, such as dampeners and wedge shaped locking mechanisms associated with the blade 200, just to name a couple of examples.

FIG. 2B shows a back view of the storage media blade 200 wherein the storage media blade 200 is populated with nine disc drives 206. The storage media blade 200 receives and transmits data over a blade SAS (Serial Attached SCSI) connector 224 receives power over a blade power connector 222. As a skilled artisan will appreciate, a variety of connector types and configurations can be used to accomplish the same functionality. A rear blade plate 218 provides support for a connector shroud 220 which not only protects the connectors 222 and 224 but provides a mounting location for an uninterruptible power and communication system, such as flex cable linkage 130.

FIG. 2C shows the back side 256 of the bezel module 202. The bezel module 202, in one embodiment of the present invention, is adapted for easy replacement should a failure occur. Herein, the bezel module 202 can accommodate two fans (not shown) in two bezel fan housings 252 and 254 that can pull air through vents 250 in the face of the bezel module 202 for cooling the disc drives 206. Power is provided to the bezel module 202 via a connector 254. In one embodiment, a locking feature (not shown) can optionally be used with the bezel module 202 for rapid access.

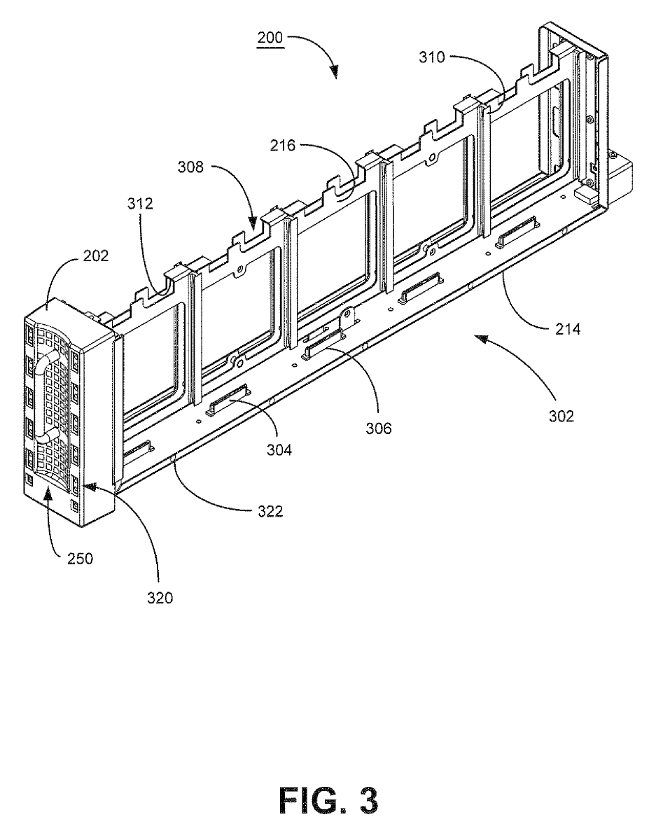

FIG. 3 shows the storage media blade 200 of FIG. 2A without disc drives 206. The HDA storage media blade 200 generally comprises a frame 302 that can accommodate a bezel module 202, a blade plate 214 and a mid-plane frame 216 capable of supporting retaining mechanisms 204 in accommodating retaining mechanism locations 308. The blade plate 214 comprises connector openings 306 for SAS (Serial Attached SCSI) connectors 304 integrated with a blade plate board (not shown) attached to the underside of the blade plate 214. Disc drives 206 are adapted to plug into the SAS connectors 304 in a male/female relationship for linking to power and communication. The blade plate 214 can, optionally, comprise base plate indication lights 322, such as LEDs (Light Emitting Diode) or terminations of light pipes, connected to the bezel indication lights 320 located on the face of the bezel module 202. The indication lights 320 and 322 indicate activity and functionality of any particular disc drive 206. The base plate indication lights 322 can provide drive 206 location, for use by an operator for example, to the coinciding bezel indication light 320 when the blade 200 is in at least an extended position. As is appreciated by one skilled in the art, the blade 200 is not limited to SAS connectors 304 rather a variety of alternate connector configurations can be substituted without deviating from the functionality of the present invention.

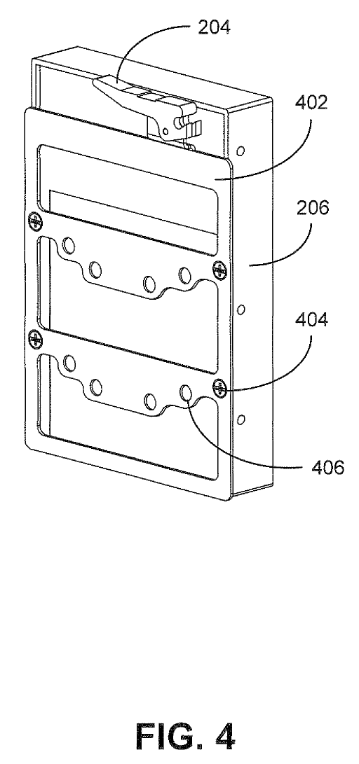

FIG. 4 shows a retaining mechanism 204 of the illustrative commercial HDA embodiment in more detail. The retaining mechanism 204 is generally comprised of a latch 204 pivotally attached to a disc drive retaining plate 402. The retaining plate 402 is attached to the drive 206 by four screws 404 aligned with mounting holes (not shown) in the disc drive 206. The retaining plate 402 can be configured with additional mounting holes 406 to accommodate alternative form factor drives, such as 2.5 inch, or 1 inch mini drives for example. The latch 204 is adapted to cooperate with a retaining structure 312 shown in the frame 200 of FIG. 3. The retaining plate 402 is adapted to slideably engage accommodating retaining flanges 310 located at the mid-plane frame 216 of FIG. 3 whereby the disc drive is aligned to connect with a connector 304. A spring ejection mechanism, not shown, can also be used. As is appreciated by one skilled in the art, there are a number of alternative retaining and ejecting configurations that accomplish the same functionality.

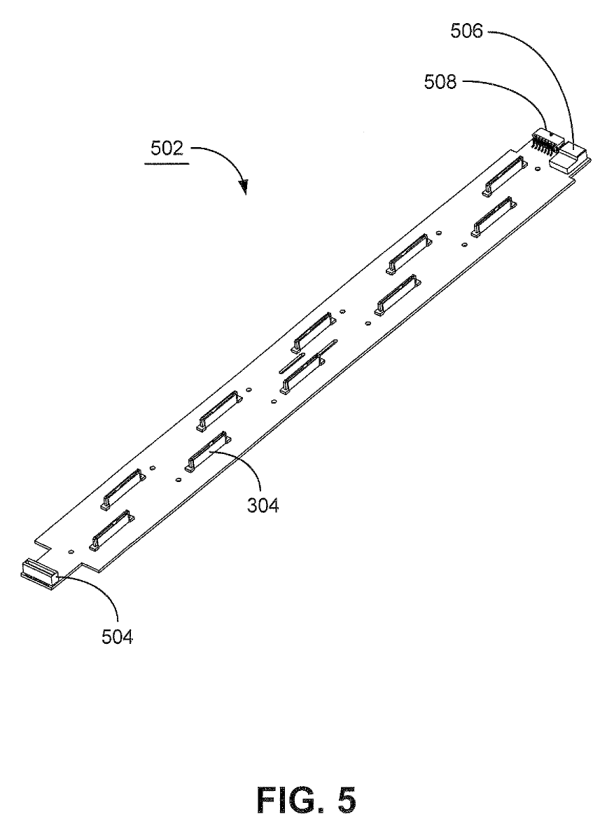

FIG. 5 shows a top view of the blade plate board 502 of the illustrative commercial HDA embodiment in more detail. The blade plate board 502 is a substrate adapted to support power and communication pathways in addition to connector structures, such as SAS connectors 304, connected to the pathways. The blade plate board 502 is substantially fixedly attached to the underside of the blade plate 214 via screws in this example. The board provides for ten SAS connectors 304, a bezel module connector 504, an in-band connector 506, for providing communication between a drive 206 (such as SAS communication) and a server (not shown) for example, and an out-of-band connector 508, for providing power and control components such as the bezel module 504, for example.

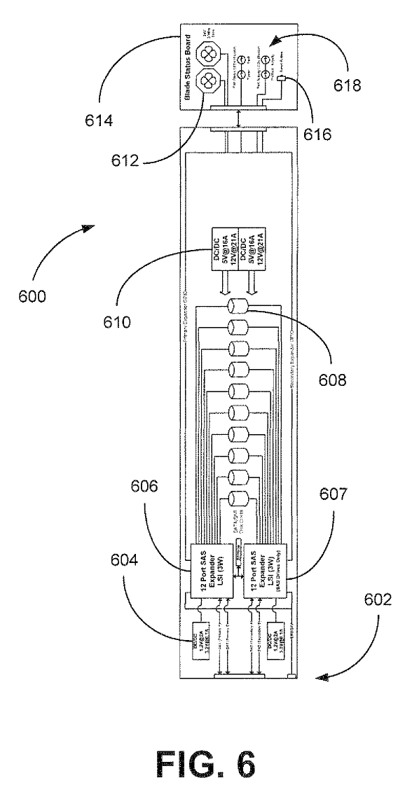

FIG. 6 is an illustration of an embodiment of a blade board schematic layout 600 of the blade plate board 502 of FIG. 5 capable of being used with the storage media blade 200 of FIG. 2A. As illustrated, power and communication are received from the HDA unit 100 from the HDA connector end 602 of the board layout 600. In general, the board 502 provides a pathway between an initiator, such as a server, and a target, such as a disc drive 608 wherein communication may pass through one or more port expanders, or other routers, to complete a target path between the initiator and target. In this configuration, the board comprises two port expanders 606 and 607, such as an SAS X12A expander chip, or alternatively a X36 expander chip just to name two examples) from LSI Logic of Milpitas, Calif., each capable of routing communication between a server, for example, and any of the ten drives 608 communicatively linked with the storage media blade 200. In this configuration, the storage media blade 200 only requires one primary port expander 606 with twelve ports to fully operate; however the back-up port expander 607 serves in a redundant port expander should the primary port expander 606 fail. In this configuration, a port expander 606 is a routing device which dedicates ten ports to the ten disc drives 608 and two ports communicate with two other devices, such as two servers or a server and another board or port expander, for example. One skilled in the art will appreciate that routing data can be accomplished with a variety of routing devices which are not limited to a port expander. Multiple blade plate boards 502 can be interconnected via additional port expanders, such as port expanders 606 and 608, on other boards 502 which can serve a purpose to provide communication for multiple devices, such as multiple servers or other clients, for example. The board layout 600 is also shown to comprise two redundant 3.3V/1.2V power supply controllers 604 for the port expanders 606 and 607. Two redundant 5V/12V power supply controllers 610 are, at least, dedicated to the disc drives 608.

Also shown in FIG. 6 is a schematic for the bezel module layout 614 of the bezel module 202 of FIG. 2A. The bezel module layout 614 shows two fans 612 (which optionally can serve as redundant units), a reset button 616 for resetting power to just the storage media blade 200 and not the entire HDA unit 100, and status LEDs. The status LEDs can include, for example, a system status LED, individual drive status LED, Ethernet status/Ethernet ports system management LEDs, or any other activity indicating device. As one skilled in the art will appreciate, there are a number of optional board layouts the can complete the primary function of the board 502 which is to transmit power to components associated with the board 502 and direct communication between at least a drive 608 and a server, for example.

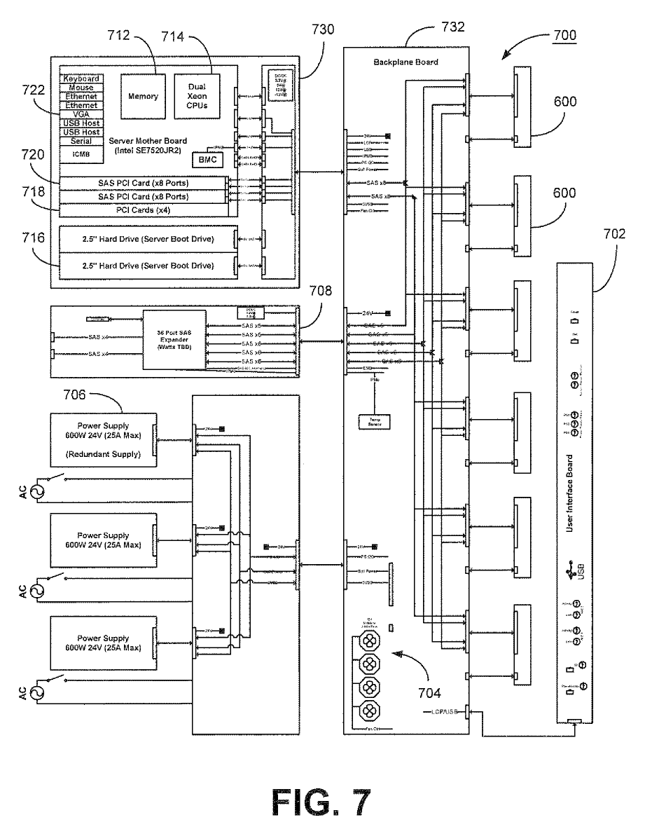

FIG. 7 is an illustration of one optional configuration of an HDA unit schematic layout 700 consistent with embodiments of the present invention. As shown, the HDA layout 700 generally comprises a server unit layout 730, a 36-port SAS Expander port layout 708 (or optionally redundant 36-port expanders), a power supply system layout 706 with redundancy, a backplane board layout 732, a user interface board layout 702 and six blade plate board layouts 600 as shown in detail in FIG. 6. With reference to the server unit layout 730, shown therein are redundant server boot drives 716 (but as one skilled in the art would recognize, alternative storage devices could be used in place of a boot drive 716), redundant SAS PCI cards 720 each comprising eight ports and location for accommodating four additional PCI cards 718, user interface 722, dynamic memory 712 and dual. CPU (Central Processing Units) 714. The six blades 600 and user interface board 702 connect to the backplane board 732 through which power is transmitted and communication can be exchanged. The backplane board 732, in this configuration) is capable of providing power and control to four (or more or less) cooling fans 704. The HDA unit 100 can show a low level operational status and basic functionality for an operator via the user interface board 702 which can comprise a power switch, a reset switch, and identification button for various elements within the HDA unit 100, USB connectors for flash key drives, keyboard and mouse connections from the front of the unit 100, wireless devices, etc., in addition to status lights for general system status, Ethernet status, etc. Optional configurations can include additional port expanders and more complex server/motherboard system(s) without deviating from the spirit of the present invention.

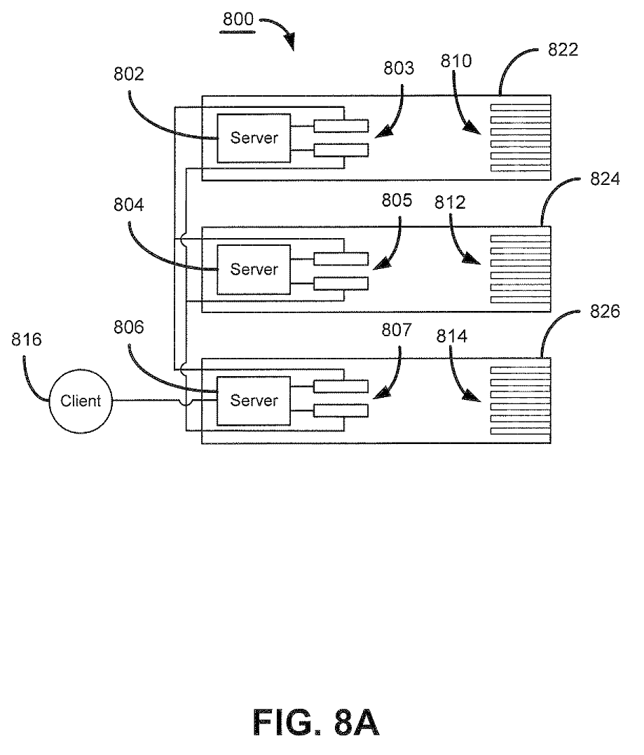

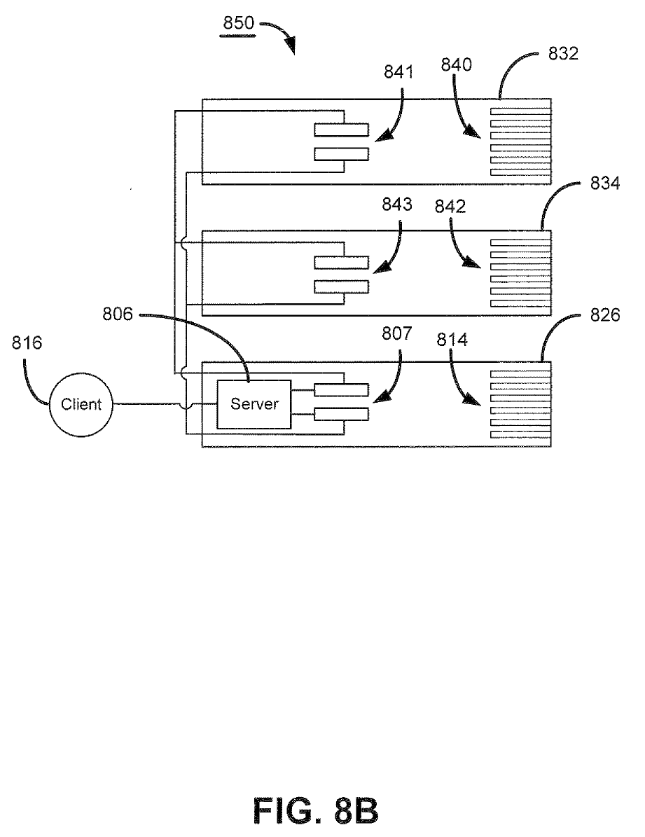

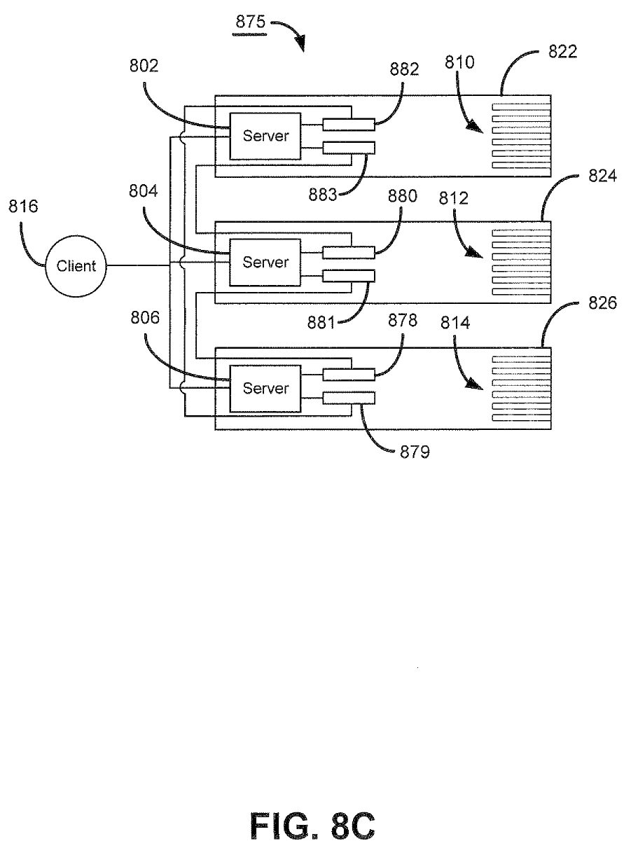

FIG. 8A is an illustration of an interconnected multi-HDA system schematic layout 800. As shown, three HDA units 822, 824 and 826 are interconnected through respective routers 803, 805, 807, such as dual 36-port SAS expanders, and servers 802, 804 and 806. The third HDA unit 826 can be connected to a network client 816 over a pathway such as ISCSI, Ethernet, Fiber channel, etc. The server boxes 802, 804 and 806 can, optionally, be interconnected further serving as a failsafe in the event a server box fails. All HDA units 822, 824 and 826 can function independently saving data on each of the associated storage media blades 810, 812, 814. As will be appreciated by a skilled artisan, there are a variety of ways to interconnect the multiple HDA units 822, 824 and 826 with the general interconnected functionality as shown without deviating from the present invention. It should also be clear that the three HDA units 822, 824 and 826 are illustrative and that a multi-HDA system can comprise an unlimited number of HDA units.

FIG. 8B is an illustration of a master HDA and add-on storage media unit layout 850. In this configuration, two add-on storage media units 832 and 834 are interconnected through routers 841 and 843, respectively, whereby the server 806 operates as a master unit for all of the storage media blades 814, 840 and 842. The HDA unit 826 can also interface with a client 816. As will be appreciated by a skilled artisan, there are a variety of ways to interconnect a master HDA unit 826 with multiple add-on units 832 and 834 while preserving the general interconnected functionality as shown without deviating from the spirit of the present invention.

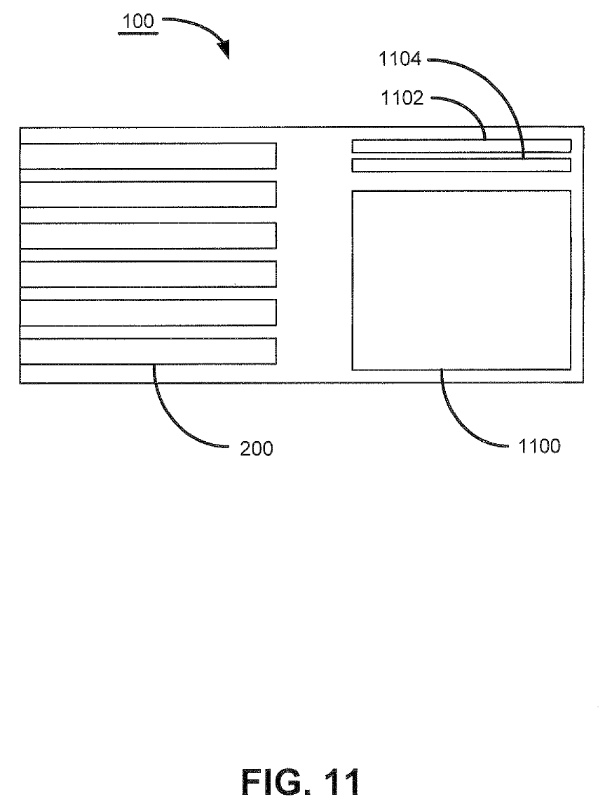

FIG. 8C is an illustration of a looped connected multi-HDA system schematic layout 875. As shown, the client 816 can be in communication with the three HDA units 822, 824 and 826 over a network. In one embodiment, a server, such as server 806, can be the primary, or active, server and the other servers 802 and 804, passive servers. As shown, a first HDA unit 826 is connected to a second HDA unit 824 via a first port expander 878 associated with the first HDA unit 826 and a second port expander 881 associated with the second HDA unit 824. The second HDA unit 824 is connected to a third HDA unit 822 via a third port expander 880 associated with the second HDA unit 824 and a fourth port expander 883 associated with the third HDA Unit 822. Optionally, the third HDA unit 822 can be connected to the first HDA unit 826 via fifth port expander 882 associated with the third HDA unit 822 and a sixth port expander 879 associated with the first HDA unit 826. In the event a server fails, such as the second server 804 associated with second HDA unit 824, a different server, such as the first server 806 associated with first HDA unit 826, can function as the active server effectively bypassing the failed second server 804. In one embodiment of the present invention, a server unit, such as server 804, can be configured to be hot-swappable, that is removable without interruption to the system. The HDA units, such as the second HDA unit 824, can be adapted to accommodate the second server 804, or any number of different modular units such as another server or RAID controller for example, in a universal module space (described in detail in FIG. 11) whereby the server 804 can be removed without interruption to the system 875. For example, the bypassing functionality effectively bypassing a failed server unit can be identically used to bypass a server with a mother board if removed from the system, such as the system 875, when in operation without interruption to the system.

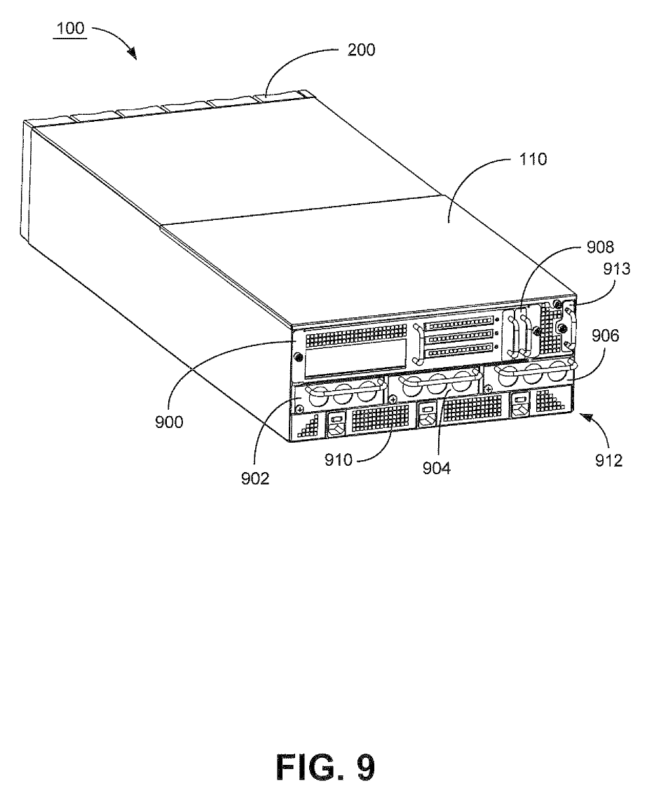

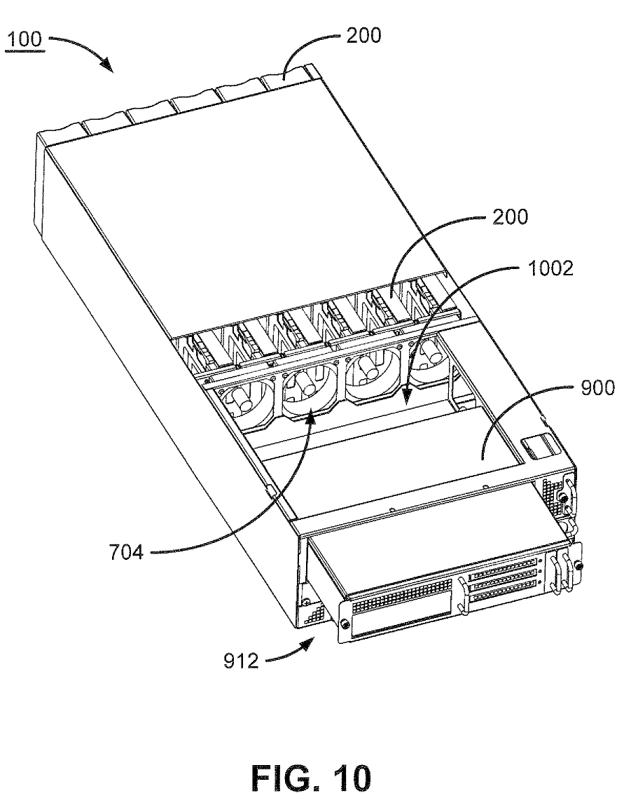

With reference to FIGS. 9 and 10, shown therein is an. embodiment of HDA unit 100 with the back surface 912 presented. The HDA unit 100 comprises a removable server unit 900 that can comprise two modular boot drives 908. Also shown are three removable power supplies 904, 904 and 906 and modular port expanders 9. Ventilation holes 910 are shown distributed on much of the back side 912 as shown for general HDA 100 cooling. FIG. 10 shows the HDA unit 100 with the removable panel 110 taken off exposing an interior portion. 1002 adapted to accommodate the removable server unit 900 (which is shown partially in the HDA unit 100). In this illustration four of the cooling fans 704 are shown for providing cooling to the storage media blades 200.

FIG. 11 is a block diagram of a top view of the HDA unit 100 without the cover 106 and removable panel 110. Shown therein are six storage media blades 200, a first and second port expander unit 1102 and 1104, respectively, and a universal module space 1100. The universal module space 1100 is adapted to functionally accommodate a variety of modular units, for example, a server, such as the server unit 900 of FIG. 9, a RAID controller, a JBOD (Just a Bunch of Disc [drives]), a channel bridge (such as a SAS to fiber channel bridge), etc. In one embodiment, a modular unit, such as the server unit 900, can comprise a sled apparatus (not shown) adapted to cooperate with features in the universal module space 1100 for efficient insertion and removal from the unit 100. Means to electrically and communicatively link the HDA unit 100 with a module can include a universal set of electrical contacts, or alternatively, specific sets of contacts disposed in the HDA unit 100 dedicated for specific modular units. As one skilled in the art will appreciate, there are a variety of ways to link a module with the HDA unit 100 when installed in the universal module space 1100. An external server can interact with the HDA unit 100 via the port expander units 1102 and 1104, or equivalent routing system(s).

Generally speaking, in one aspect of the present invention, a storage unit can comprise: a frame defining a storage unit interior space; at least one media blade capable of removably supporting a plurality of storage elements; the media blade adapted to provide at least a communication pathway and power between the storage elements and the storage unit; the media blade capable of being at least partially moved into and out from the interior space without interruption of the power and communication. The storage unit can further comprise a latch mechanism to prevent the media blade from totally being removed from the unit interior space. The storage unit can further be adapted to be received by an accommodating opening in the frame. Additionally, the storage unit can be adapted to accommodate six media blades.

The media blade can be partially moved between a retracted position wherein substantially all of the storage elements are within the interior space and an extended position wherein substantially all of the storage elements are external to the interior space. Additionally, the storage blade can be retained by a locking mechanism and supported by the storage unit when in the extended position.

The storage unit can optionally comprise storage elements selected from one of the group consisting of: a disc drive, flash memory (or other kind of solid state storage memory), compact disc, magneto-optical drive, floppy disc drive and holographic drive.

The power and communication can be provided to the media blade by a power and communication linking device selected from one of the group consisting of: a ribbon cable, at least one independent conductive wire, a flexible cable, at least one group of conductive wires. Additionally, the power and communication linking device can comprise a tangling prevention device. Furthermore, the tangling prevention device can be a flex chain linkage. Optionally, the tangling prevention device can be a spring loaded spindle. The power can be provided by a brush and conductive lead system and the communication can be transmitted wirelessly.

The storage media blade of the storage unit can comprise a base for supporting a base board through which the communication and power can be transmitted, a bezel module, a mid-plane frame, blade power connector and blade communication connector. The blade base can accommodate a plurality of storage element power and communication connectors for the storage elements. The storage clement power and communication connectors can be Serial Attached Small Computer System Interface connectors. The bezel module can be removably attached to the storage media blade and comprises a handle, at least one indication light associated with each of the storage elements, at least one fan speed controllable and a blade reset button. The blade power and blade communication connectors connect to the power and communication linking device. The storage elements can be disposed on either side of the mid-plane frame. The storage elements can be disc drives wherein the disc drive can optionally be at least two different storage density capacities, different disc rotation speeds, or different disc drive form factors. In the embodiment wherein the storage elements are disc drives magnetic discs comprised by the disc drives can rotate in opposite directions when mounted on opposite sides of the mid-plane frame. The storage elements can optionally be mounted to a mid-plane retaining plate that cooperates with the mid-plane to hold the storage elements substantially in place when electrically connected to the base board. The retaining plate can accommodate alternate form factor storage elements. The storage media blade can further comprise a latch mechanism to removably and substantially lock the storage element to the blade. The base board of the blade further can comprise storage element activity indicators for each storage element corresponding to the at least one indication light associated with each of the storage elements on the bezel board. The storage element activity indicators can be Light Emitting Diodes located in proximity to each storage element. As a skilled artisan would recognize, other light indicating devices/emitters or light sources and reflecting devices, etc. can be used to accomplish the same result as a Light Emitting Diode without departing from the present invention.

The storage unit can further be adapted to cooperate with a second storage unit to comprise a storage system capable interacting with a host. All of the storage units can be substantially identical, or optionally the second storage unit can be just a bunch of storage elements or drives (JBOD) such as, for example, capable of being field adaptable to be able to switch from a JBOD to full operating mode. Both storage units can each further comprise a universal module space located in the interior space adapted to accommodate a server module, i.e. a first modular server unit for the original storage unit and a second modular server unit for the second storage unit. The first modular server unit can function as a master server unit taking over server operations for both the original storage unit and the second storage unit. Optionally, the second modular server unit can be made to function as the maser server unit. In one embodiment, the second modular server unit can be made to function as the maser server unit when the first server unit fails wherein functionality of the system remains uninterrupted. In an alternative embodiment, the second modular server unit can be made to function as the maser server unit when the first server unit is removed in a hot-swap operation wherein functionality of the system remains uninterrupted. The storage system can comprise a third storage unit wherein the storage units can be interconnected through a loop system wherein the storage unit from claim 1 is connected to the second storage unit and the second storage unit is connected to the third storage unit. The storage units can all interconnected via router devices. Optionally, the original storage unit can be connected to both the second storage unit and the third storage unit; the second storage unit can be connected to both the original storage unit and the third storage unit.

In another aspect of the present invention, a storage unit comprising a frame that defines and interior space, the storage unit can be capable of performing the steps of: receiving a first data package from a host; storing the first data package on a first storage media blade wherein the first storage media blade comprises a plurality of data storage elements; moving the first storage media blade from a first position that is substantially within the interior space to a second position that is less than substantially within the interior space without interrupting the storing.

The storage unit method can optionally be further defined so that the first position is when at least all of the storage elements are within the interior space. The second position can be when all of the storage elements are out side of the interior space. The method can further comprising storing the first data redundantly using a RAID level format, such as RAID level-5 for example. In one embodiment, at least one of the plurality of storage elements can be removed from the first storage media blade when in the second position without substantially interrupting storing of the first data. The removed storage element can be replaced with a different form factor storage element, a different storage capacity storage element, or a different data handling rate.

The method can further comprise exchanging a modular unit in a universal space that is substantially within the interior space without interruption to the storing of the first data. The modular unit can be of the group consisting of: a JBOD, a server unit, RAID controller, a storage array and a routing unit.

The storage unit method can further comprise receiving a second data package from the host; storing the second data package on a second storage media blade wherein the second storage media blade comprises a second plurality of data storage elements; moving the second storage media blade from a first position that is substantially within the interior space to a second position that is less than substantially within the interior space without interrupting the storing of the second data. This can further comprise storing the second data redundantly in a RAID level format on the second storage media blade. Alternatively, this can further comprise storing the second data redundantly in a RAID level format across the first and second storage media blades.

In yet another aspect of the present invention, a storage system can comprise a first and second storage unit, the storage system capable of performing the steps of: receiving a first data package from a host; storing the first data package on a first storage media blade associated with the first storage unit wherein the first storage media blade comprises a plurality of data storage elements; moving the first storage media blade from a first position that is substantially within the interior space to a second position that is less than substantially within the interior space without interrupting the storing.

The method can further comprise receiving a second data package from the host; storing the second data package on a second storage media blade associated with the second storage unit wherein the second storage media blade comprises a plurality of data storage elements; moving the second storage media blade from a first position that is substantially within the interior space to a second position that is less than substantially within the interior space without interrupting the storing. This can further comprise storing the second data redundantly in a RAID level format across the first and second storage units. Optionally, this can further comprise the first storage unit controls the storage of the first data on the first unit and the first storage unit controls the storage of the second data on the second unit. Optionally this can further comprise the second storage unit assumes control of the storage of the first and second data if the first storage unit fails to control the storage of the first and second data.

In yet another aspect of the present invention, a storage system comprising at least one storage unit, the storage unit can comprise: a frame defining a storage unit interior space; at least one media blade capable of removably supporting a plurality of storage elements wherein the media blade is adapted to provide a communicating path between the storage elements and the storage unit; the media blade capable of moving between a retracted position wherein substantially all of the storage elements are within the interior space and an extended position wherein substantially all of the storage elements are external to the interior space; a means to provide uninterrupted power and communication to the media blade when the media blade is at or between the retracted and extended positions.

In yet another aspect of the present invention a storage unit comprising a frame that defines and interior space, a means for storage unit operation can comprise: means for receiving a first data package from a host; means for storing the first data package on a first storage media blade wherein the first storage media blade comprises a plurality of data storage elements; means for moving the first storage media blade from a first position that is substantially within the interior space to a second position that is less than substantially within the interior space without interrupting the storing.

Optionally, the means plus function embodiments can further include, means for storing the first data redundantly using a RAID level format. Means for further receiving a second data package from the host; means for storing the second data package on a second storage media blade wherein the second storage media blade comprises a second plurality of data storage elements; means for moving the second storage media blade from a first position that is substantially within the interior space to a second position that is less than substantially within the interior space without interrupting the storing of the second data.

The means plus function can further comprise means for storing the second data redundantly in a RAID level format on the second storage media blade or optionally means for storing the second data redundantly in a RAID level format across the first and second storage media blades.

The means plus function can further comprise means for exchanging a modular unit in a universal space that is substantially within the interior space without interruption to the storing of the first data.

In another aspect of the present invention, a storage system comprising a first and second storage unit, a means for the storage system to operate can comprise: a means for receiving a first data package from a host; a means for storing the first data package on a first storage media blade associated with the first storage unit wherein the first storage media blade comprises a plurality of data storage elements; a means for moving the first storage media blade from a first position that is substantially within the interior space to a second position that is less than substantially within the interior space without interrupting the storing.

The means plus function can further comprise means for receiving a second data package from the host; means for storing the second data package on a second storage media blade associated wit the second storage unit wherein the second storage media blade comprises a plurality of data storage elements; means for moving the second storage media blade from a first position that is substantially within the interior space to a second position that is less than substantially within the interior space without interrupting the storing. Additionally, this can further comprise a means for storing the second data redundantly in a RAID level format across the first and second storage units.

It is to be understood that even though numerous characteristics and advantages of various embodiments of the present invention have been set forth in the foregoing description, together with the details of the structure and function of various embodiments of the invention, this disclosure is illustrative only, and changes may be made in detail, especially in matters of structure and arrangement of parts within the principles of the present invention to the full extent indicated by the broad general meaning of the terms in which the appended claims are expressed. For example, alternate board layouts and features specific to market needs can be used with an HDA, such as the HDA system 800, for example, while still maintaining substantially the same functionality without departing from the scope and spirit of the present invention. Another example can include various means to provide uninterrupted power and communication to a storage media blade, such as the storage media blade 200, when moved between a retracted and extended position while still maintaining substantially the same functionality without departing from the scope and spirit of the present invention. Although the preferred embodiments described herein are directed to disc drive systems, such as the disc drive blade 200, and related technology, it will be appreciated by those skilled in the art that the teachings of the present invention can be applied to other systems and storage media, without departing from the spirit and scope of the present invention.

It will be clear that the present invention is well adapted to attain the ends and advantages mentioned as well as those inherent therein. While presently preferred embodiments have been described for purposes of this disclosure, numerous changes may be made which readily suggest themselves to those skilled in the art and which are encompassed in the spirit of the invention disclosed.

1. A data storage unit having a source of electronic communication and a source of electronic power, the data storage unit comprising:
a frame defining a storage unit interior space,
at least one media blade accommodating a plurality of storage elements;
the plurality of storage elements receiving at least electronic communication and electronic power from said electronic communication source and said electronic power source via said media blade;
the media blade adapted for being at least partially moved into and out from the interior space without interruption of the communication and power.

2. The storage unit of claim 1 further comprising a latch mechanism to prevent the media blade from totally being removed from the unit interior space.

3. The storage unit of claim 1 wherein said media blade is adapted to be received by an accommodating opening in the frame.

4. The storage unit of claim 3 wherein the storage unit is adapted to accommodate a plurality of media blades.

5. The storage unit of claim 1 wherein the media blade is partially moved between a retracted position wherein substantially all of the storage elements are within the interior space and an extended position wherein substantially all of the storage elements are external to the interior space, the media blade remains supported by data storage unit while the media blade is partially moved.

6. The storage unit of claim 5 wherein the media blade is adapted to be supported by the storage unit when fully in the extended position.

7. The storage unit of claim 1 wherein the media blade comprises a base for supporting a base board, the communication and the power can be transmitted via the base board.

8. The storage unit of claim 7 wherein the base can accommodate a plurality of storage element power and communication connectors for the storage elements.

9. The storage unit of claim 8 wherein the storage element power and communication connectors are Serial Attached Small Computer System Interface connectors.

10. The storage unit of claim 1 wherein the power and the communication are provided to the media blade by a power and communication linking device selected from one of the group consisting of: a ribbon cable, at least one independent conductive wire, a flex cable, at least one group of conductive wires.

11. The storage system of claim 10 wherein the power and communication linking device comprises a tangling prevention device.

12. A method of operating a data storage unit wherein the data storage unit comprises a frame that defines an interior space, the method comprising the steps of:
receiving a first data package from a host;
storing the first data package on at least one of a plurality of data storage elements that are supported by a first media blade;
moving the first media blade along a guided pathway adapted for the first media blade from a first position that is substantially within the interior space to a second position that is less than substantially within the interior space without interrupting the storing.

13. The method of claim 12 wherein the first position is when at least all of the storage elements are within the interior space.

14. The method of claim 13 wherein the second position is when all of the storage elements are out side of the interior space.

15. The method of claim 12 further comprising storing the first data redundantly using a redundant data storing technique.

16. The method of claim 12 further comprising receiving a second data package from the host;
storing the second data package on a second media blade wherein the second media blade comprises a second plurality of data storage elements;
moving the second media blade along a guided pathway from a first position that is substantially within the interior space to a second position that is less than substantially within the interior space without interrupting the storing of the second data.

17. The method of claim 16 further comprising storing the second data redundantly using a redundant data storing technique across the first and second media blades.

18. The method of claim 12 wherein at least one of the plurality of data storage elements is removed from the first media blade when in the second position without substantially interrupting storing of the first data.

19. The method of claim 18 wherein the removed storage element is replaced with a storage element selected from the group consisting of: a different form factor storage element, a different storage capacity storage element, a storage element having a different data handling rate.

20. A storage system comprising:
a frame defining a storage system interior space;
at least one media blade capable of removably supporting a plurality of storage elements wherein the media blade provides a communicating path between the storage elements and the storage system;
the media blade moving while being supported by the storage system between a retracted position wherein substantially all of the storage elements are within the interior space and an extended position wherein substantially all of the storage elements are external to the interior space;
a means to provide uninterrupted power and communication to the media blade when the media blade is at or between the retracted and extended positions.
